(19) United States
(12) Patent Application Publication
(10) Pub. No.: US 2025/0346110 A1
(43) Pub. Date: Nov. 13, 2025

(54) HEAT UTILIZATION CIRCUIT

(71) Applicant: TOYOTA JIDOSHA KABUSHIKI KAISHA, Toyota-shi (JP)

(72) Inventor: Ryo MICHIKAWAUCHI, Numazu-shi (JP)

(73) Assignee: TOYOTA JIDOSHA KABUSHIKI KAISHA, Toyota-shi (JP)

(21) Appl. No.: 19/016,223

(22) Filed: Jan. 10, 2025

(30) Foreign Application Priority Data
May 13, 2024 (JP) 2024-077855

(51) Int. Cl. B60K 11/02

(52) U.S. Cl. CPC B60K 11/02

(57) ABSTRACT

A heat utilization circuit performs heat exchange between the cooling medium cooled by the inverter and the transaxle when the temperature of the cooling medium cooled by the transaxle is equal to or higher than the temperature of the cooling medium cooled by the inverter, and suppresses heat exchange between the cooling medium cooled by the inverter and the transaxle when the temperature of the cooling medium cooled by the transaxle is lower than the temperature of the cooling medium cooled by the inverter.

### CROSS-REFERENCE TO RELATED APPLICATION

This application claims priority to Japanese Patent Application No. 2024-077855 filed on May 13, 2024, incorporated herein by reference in its entirety.

### BACKGROUND

### 1. Technical Field

The present disclosure relates to heat utilization circuits.

### 2. Description of Related Art

It is known to raise the temperature of an object to be heated (hereinafter also referred to as “heating target”) by utilizing heat of a cooling medium that has cooled an object to be cooled (hereinafter also referred to as “cooling target”) in a vehicle. Japanese Unexamined Patent Application Publication No. 2020-165604 (JP 2020-165604 A) discloses that an inverter is used as a heat absorption source of a chiller for heating.

### SUMMARY

JP 2020-165604 A discloses only the inverter as a cooling target, and does not disclose utilization of heat of a cooling medium when there is a plurality of cooling targets. When the temperature rising rates of a plurality of cooling targets are different from each other, the temperature of a heating target may not be efficiently raised with the heat of the cooling medium that has cooled the cooling targets. For example, when the cooling medium whose temperature has been raised as it has cooled a cooling target having a relatively high temperature rising rate is used to cool a cooling target having a relatively low temperature rising rate, heat may be dissipated, which may reduce the temperature raising efficiency of the heating target.

An object of the present disclosure is to efficiently utilize heat exchanged by a cooling medium that cools a plurality of cooling targets.

The present disclosure provides a heat utilization circuit. The heat utilization circuit includes:
a first cooling channel through which a cooling medium configured to cool an inverter flows; and
a second cooling channel through which a cooling medium configured to cool a transaxle flows.

The heat utilization circuit is configured to
when a temperature of the cooling medium that has cooled the transaxle is equal to or higher than a temperature of the cooling medium that has cooled the inverter, perform heat exchange between the cooling medium that has cooled the inverter and the transaxle, and
when the temperature of the cooling medium that has cooled the transaxle is lower than the temperature of the cooling medium that has cooled the inverter, reduce the heat exchange between the cooling medium that has cooled the inverter and the transaxle.

With the present disclosure, it is possible to efficiently utilize heat exchanged by a cooling medium that cools a plurality of cooling targets.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram for explaining a configuration of a heat utilization circuit according to the present embodiment;

FIG. 2 is a flowchart for explaining the operation of the heat utilization circuit shown in FIG. 1;

FIG. 3 is a diagram for explaining a configuration of a heat utilization circuit according to a modification of the present embodiment;

FIG. 4 is a diagram for explaining a configuration of a heat utilization circuit according to a modification of the present embodiment;

FIG. 5 is a diagram for describing a configuration of a heat utilization circuit according to a modification of the present embodiment; and

FIG. 6 is a diagram for explaining a configuration of a heat utilization circuit according to a modification of the present embodiment.

### DETAILED DESCRIPTION OF EMBODIMENTS

Hereinafter, the present embodiment will be described with reference to the accompanying drawings. In order to facilitate understanding of the description, the same components are denoted by the same reference numerals as much as possible in the drawings, and redundant description will be omitted.

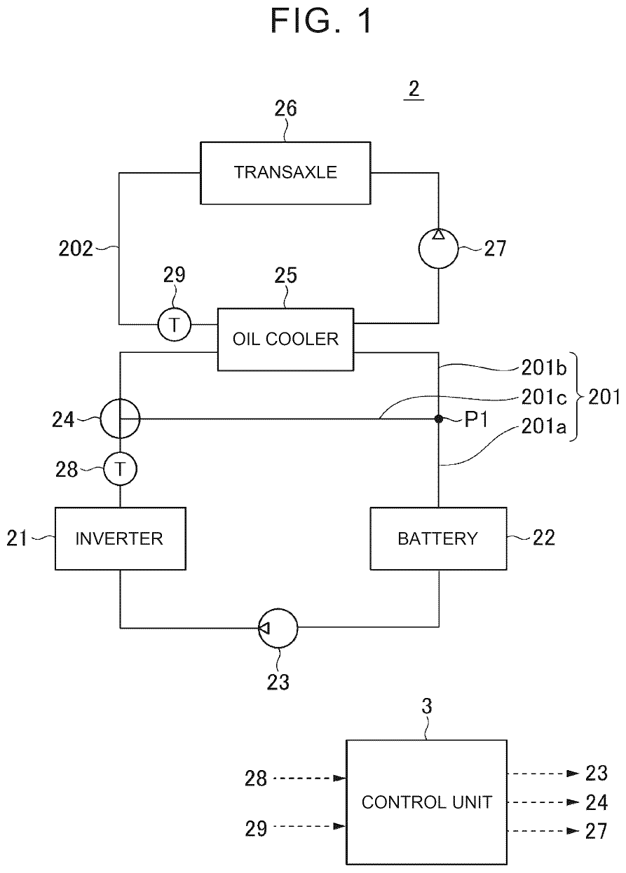

The heat utilization circuit 2 according to the present embodiment will be described with reference to FIG. 1. The heat utilization circuit 2 is a heat exchange system mounted on a vehicle. The heat utilization circuit 2 includes a first cooling channel 201 and a second cooling channel 202.

The first cooling channel 201 is a channel through which a cooling medium for cooling the inverter 21 flows. In the present embodiment, the cooling medium for cooling the inverter 21 is water. The first cooling channel 201 includes a heat recovery channel 201a, a heat exchange channel 201b, and a bypass channel 201c.

Both ends of the heat recovery channel 201a and both ends of the heat exchange channel 201b are connected to each other, and a channel for circulating the cooling medium is formed in the heat recovery channel 201a and the heat exchange channel 201b. A switching valve 24, which is a three-way valve, is provided at a part where one end of the heat recovery channel 201a and one end of the heat exchange channel 201b are connected to each other. The multiple ends of the heat recovery channel 201a and the multiple ends of the heat exchange channel 201b are connected to each other in the connecting part P1. A bypass channel 201c is provided so as to connect the switching valve 24 and the connecting part P1.

A pump 23 is provided to circulate the cooling medium in the first cooling channel 201. In the present embodiment, the heat recovery channel 201a is provided with the pump 23. In the first cooling channel 201, a temperature sensor 28 is provided so that the temperature of the cooling medium cooled by the inverter 21 can be measured. In the present embodiment, the temperature sensor 28 is provided downstream of the inverter 21 in the heat recovery channel 201a.

The Inverter 21 and the battery 22 are disposed in the heat recovery channel 201a. The inverter 21 is cooled by the cooling medium flowing through the heat recovery channel 201a. The cooling medium heated by cooling the inverter 21 exchanges heat with the battery 22, thereby raising the temperature of the battery 22.

An oil cooler 25 is provided in the heat exchange channel 201b. The oil cooler 25 is a heat exchanger for exchanging heat with the cooling medium flowing through the second cooling channel 202.

The second cooling channel 202 is a channel through which a cooling medium for cooling the transaxle 26 flows. In the present embodiment, the cooling medium for cooling the transaxle 26 is oil.

A transaxle 26, a pump 27, a temperature sensor 29, and an oil cooler 25 are disposed in the second cooling channel 202. The pump 27 is provided so as to circulate the cooling medium in the second cooling channel 202. The temperature sensor 29 is provided on the downstream side of the transaxle 26 and on the upstream side of the oil cooler 25 so that the temperature of the cooling medium cooling the transaxle 26 can be measured. The oil cooler 25 is a heat exchanger for exchanging heat with the cooling medium flowing through the first cooling channel 201.

The control unit 3 includes, as electrical components, a microcomputer (hereinafter referred to as a microcomputer), a data transfer circuit, a power supply circuit, and a power supply detection circuit. The microcomputer includes a Central Processing Unit (CPU), Read Only Memory (ROM), Random Access Memory (RAM), and a flash memory.

Temperature data indicating the temperature of the cooling medium cooling the inverter 21 is input from the temperature sensor 28 to the control unit 3. Temperature data indicating the temperature of the cooling medium cooling the transaxle 26 is input from the temperature sensor 29 to the control unit 3. The control unit 3 outputs a drive signal to the pump 23, the switching valve 24, and the pump 27.

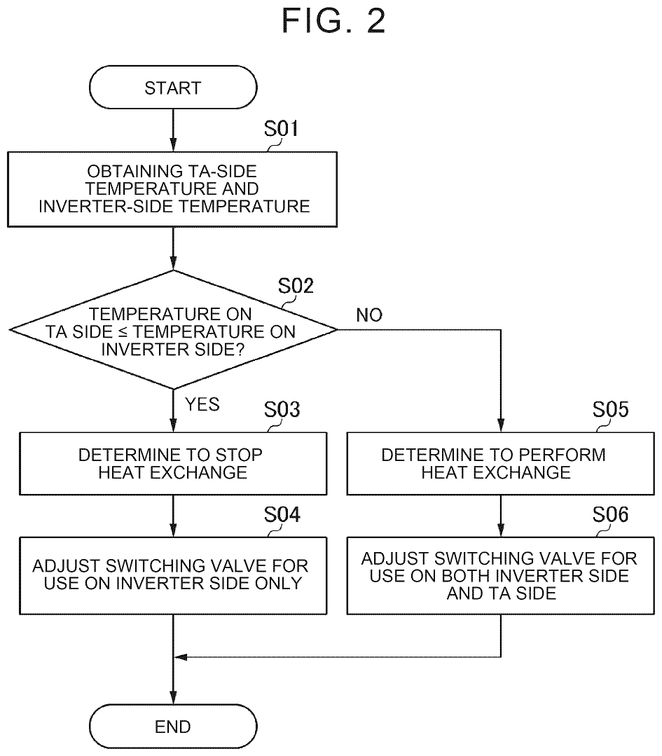

Next, the operation of the control unit 3 will be described with reference to FIG. 2. In S01, the control unit 3 acquires the transaxle-side temperature and the inverter-side temperature. The transaxle-side temperature is the temperature of the cooling medium that has cooled the transaxle 26, and is temperature data output from the temperature sensor 29. The inverter-side temperature is the temperature of the cooling medium that has cooled the inverter, and is temperature data output from the temperature sensor 28.

In S02 following S01, the control unit 3 determines whether the transaxle-side temperature is equal to or lower than the inverter-side temperature. If the transaxle-side temperature is less than or equal to the inverter-side temperature (S02: YES), processing proceeds to S03. If the transaxle-side temperature is not less than or equal to the inverter-side temperature (S02:NO), processing proceeds to S05.

In S03, the control unit 3 determines to reduce heat exchange between the cooling medium cooled by the inverter 21 and the transaxle 26. In the heat utilization circuit 2 shown in FIG. 1, heat exchange between the cooling medium cooled by the inverter 21 and the transaxle 26 is performed between the cooling medium cooled by the inverter 21 and the cooling medium cooled by the transaxle 26. Therefore, the control unit 3 determines to suppress heat exchange between the cooling medium that has cooled the inverter 21 and the cooling medium that has cooled the transaxle 26. In the description with reference to FIG. 2, the control unit 3 determines to stop the heat exchange between the cooling medium that has cooled the inverter 21 and the cooling medium that has cooled the transaxle 26.

In S04 following S03, the control unit 3 adjusts the switching valve 24 so that the temperature of the battery 22 arranged in the heat recovery channel 201a is controlled 15 by the cooling medium cooled by the inverter 21. The temperature of the battery 22 arranged in the heat recovery channel 201a is mainly increased by the cooling medium cooled by the inverter 21. The cooling medium that cools the inverter 21 and does not pass through the oil cooler 25 flows to the battery 22 more than the cooling medium that has passed through the oil cooler 25. In the description that is given with reference to FIG. 2, the control unit 3 switches the switching valve 24 so that the cooling medium cooled by the inverter 21 flows 20 all in the bypass channel 201c.

In S05, the control unit 3 makes a determination to perform heat exchange between the cooling medium having cooled the inverter 21 and the transaxle 26. In the heat utilization circuit 2 shown in FIG. 1, heat exchange between the cooling medium cooled by 25 the inverter 21 and the transaxle 26 is performed between the cooling medium cooled by the inverter 21 and the cooling medium cooled by the transaxle 26. Therefore, the control unit 3 determines to perform heat exchange between the cooling medium cooled by the inverter 21 and the cooling medium cooled by the transaxle 26.

In S06 following S05, the control unit 3 adjusts the switching valve 24 such that the temperature rise by the cooling medium that has cooled the inverter 21 and the temperature rise by the cooling medium that has cooled the transaxle 26 are performed in combination with the battery 22 disposed in the heat recovery channel 201a. In the description that is given with reference to FIG. 2, the control unit 3 switches the switching valve 24 so that the cooling medium cooled by the inverter 21 flows all in the heat exchange channel 201b. The control unit 3 may switch the switching valve 24 so that the cooling medium cooled by the inverter 21 is distributed between the heat exchange channel 201b and the bypassing channel 201c.

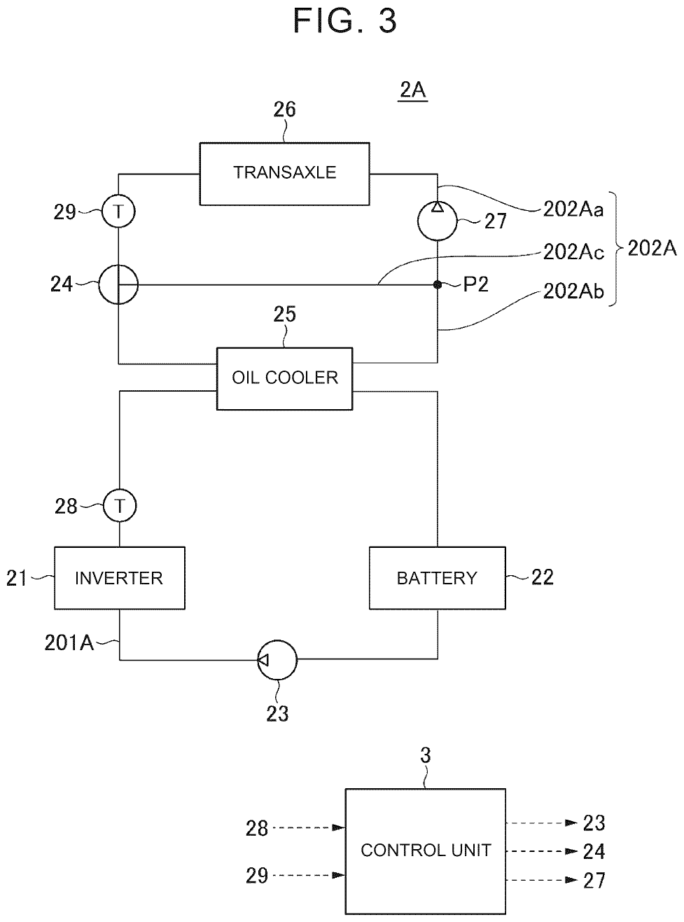

In the heat utilization circuit 2 described with reference to FIG. 1, the bypass channel 201c is provided in the first cooling channel 201, but the bypass channel may be provided in the second cooling channel. A heat utilization circuit 2A according to a modification in which the bypass channel is provided in the second cooling channel will be described with reference to FIG. 3. In describing the heat utilization circuit 2A, descriptions of parts shared with the heat utilization circuit 2 will be omitted as appropriate, and differences from the heat utilization circuit 2 will be mainly described. The heat utilization circuit 2A includes a first cooling channel 201A and a second cooling channel 202A.

The first cooling channel 201A is a channel through which a cooling medium for cooling the inverter 21 flows. In the first cooling channel 201A, an inverter 21, a pump 23, a temperature sensor 28, a battery 22, and an oil cooler 25 are disposed.

The inverter 21 is cooled by the cooling medium flowing through the first cooling channel 201A. The cooling medium heated by cooling the inverter 21 is further heated by heat exchange in the oil cooler 25, exchanges heat with the battery 22, and raises the temperature of the battery 22.

The second cooling channel 202A is a channel through which a cooling medium for cooling the transaxle 26 flows. The second cooling channel 202A includes a heat recovery channel 202Aa, a heat exchange channel 202Ab, and a bypass channel 202Ac.

Both ends of the heat recovery channel 202Aa and both ends of the heat exchange channel 202Ab are connected to each other, and a channel for circulating the cooling medium is formed in the heat recovery channel 202Aa and the heat exchange channel 202Ab. A switching valve 24 is provided at a part where one end of the heat recovery channel 202Aa and one end of the heat exchange channel 202Ab are connected to each other. The multiple ends of the heat recovery channel 202Aa and the multiple ends of the heat exchange channel 202Ab are connected to each other in the connecting part P2. A bypass channel 202Ac is provided so as to connect the switching valve 24 and the connecting part P2.

A pump 27 is provided to circulate the cooling medium in the second cooling channel 202A. In the present modification, the heat recovery channel 202Aa is provided with the pump 27. In the second cooling channel 202, a temperature sensor 29 is provided so that the temperature of the cooling medium cooled by the transaxle 26 can be measured. In the present modification, the temperature sensor 29 is provided downstream of the transaxle 26 in the heat recovery channel 202Aa.

An oil cooler 25 is provided in the heat exchange channel 202Ab. The oil cooler 25 is a heat exchanger for exchanging heat with the cooling medium flowing through the first cooling channel 201A.

The operation of the control unit 3 in the heat utilization circuit 2A is the same as that of the heat utilization circuit 2 in S01, S02, S03, and S05 described with reference to FIG. 2.

In S04, the control unit 3 adjusts the switching valve 24 so that the temperature of the battery 22 arranged in the first cooling channel 201A is controlled by the cooling medium cooled by the inverter 21. The temperature of the battery 22 arranged in the first cooling channel 201A is mainly increased by the cooling medium cooled by the inverter 21. The cooling medium cooled by the inverter 21 suppresses heat exchange with the cooling medium flowing through the second cooling channel 202A in the oil cooler 25 and flows to the battery 22. For example, the control unit 3 switches the switching valve 24 so that the cooling medium cooled in the transaxle 26 flows in the bypass channel 202Ac.

In S06, the control unit 3 adjusts the switching valve 24 such that the temperature rise by the cooling medium that has cooled the inverter 21 and the temperature rise by the cooling medium that has cooled the transaxle 26 are performed in combination with the battery 22 disposed in the first cooling channel 201A. For example, the control unit 3 switches the switching valve 24 so that all the cooling medium cooled in the transaxle 26 flows in the heat exchange channel 202Ab. Note that the control unit 3 may switch the switching valve 24 so that the cooling medium cooled in the transaxle 26 is distributed and flows in the heat exchange channel 202Ab and the bypass channel 202Ac.

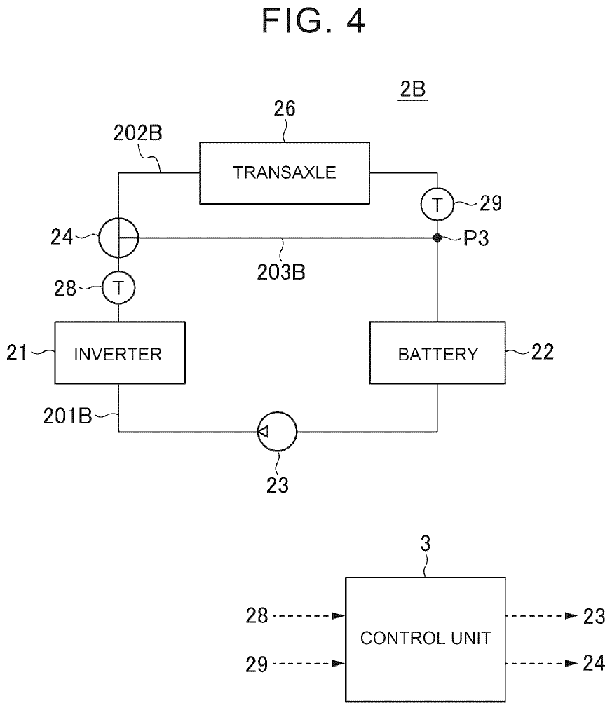

In the heat utilization circuit 2 described with reference to FIG. 1 and the heat utilization circuit 2A described with reference to FIG. 3, an embodiment in which oil is used as a cooling medium for cooling the transaxle 26 has been described. Water can also be used as the cooling medium for cooling the transaxle 26, in which case it can be shared with the cooling medium for cooling the inverter 21. A heat utilization circuit 2B using water as a cooling medium for cooling the transaxle 26 will be described with reference to FIG. 4. In describing the heat utilization circuit 2B, descriptions of parts shared with the heat utilization circuit 2 will be omitted as appropriate, and differences from the heat utilization circuit 2 will be mainly described.

As shown in FIG. 4, the heat utilization circuit 2B includes a first cooling channel 201B and a second cooling channel 202B. Both ends of the first cooling channel 201B and both ends of the second cooling channel 202B are connected to each other, and a channel for circulating water as a cooling medium is formed in the first cooling channel 201B and the second cooling channel 202B.

A switching valve 24 is provided at a part where one end of the first cooling channel 201B and one end of the second cooling channel 202B are connected. The multiple ends of the first cooling channel 201B and the multiple ends of the second cooling channel 202B are connected to each other at the connecting part P3. A bypass channel 203B is provided so as to connect the switching valve 24 and the connecting part P2.

The first cooling channel 201B includes an inverter 21, a pump 23, a temperature sensor 28, and a battery 22. The inverter 21 is cooled by the cooling medium flowing through the first cooling channel 201B. The cooling medium heated by cooling the inverter 21 exchanges heat with the battery 22, thereby raising the temperature of the battery 22. When the cooling medium heated by cooling the inverter 21 flows to the second cooling channel 202B, the transaxle 26 is cooled and further heated. When the cooling medium cooled and heated by the inverter 21 flows to the bypass channel 203B, the temperature of the battery 22 is raised as it is.

A transaxle 26 and a temperature sensor 29 are disposed in the second cooling channel 202B. In the second cooling channel 202B, a temperature sensor 29 is provided so that the temperature of the cooling medium cooled by the transaxle 26 can be measured. In the present modification, the temperature sensor 29 is provided on the downstream side of the transaxle 26.

The operation of the control unit 3 in the heat utilization circuit 2B is the same as that of the heat utilization circuit 2 in S01,S02,S03,S05 described with reference to FIG. 2.

In S04, the control unit 3 adjusts the switching valve 24 so that the temperature of the battery 22 arranged in the first cooling channel 201B is controlled by the cooling medium cooled by the inverter 21. When the temperature of the battery 22 disposed in the first cooling channel 201B is increased by the cooling medium that has cooled the inverter 21, the cooling medium that has cooled the inverter 21 is suppressed from exchanging heat with the transaxle 26 and flows to the battery 22. For example, the control unit 3 switches the switching valve 24 so that the cooling medium cooled in the transaxle 26 flows in the bypass channel 203B.

In S06, the control unit 3 adjusts the switching valve 24 so that the temperature increase by the cooling medium that has cooled the inverter 21 and the temperature increase by the cooling medium that has cooled the transaxle 26 are performed in combination with the battery 22. For example, the control unit 3 switches the switching valve 24 so that the cooling medium cooled by the inverter 21 flows all in the second cooling channel 202B. The control unit 3 may switch the switching valve 24 so that the cooling medium cooled by the inverter 21 is distributed to the second cooling channel 202B and the bypass channel 203B.

The description with reference to FIGS. 1, 2, 3, and 4 relates to a heat utilization circuit in which heat recovered by cooling an inverter or a transaxle is applied to a battery. Heat need not necessarily be directly applied to the battery, and may be applied to an element other than the battery.

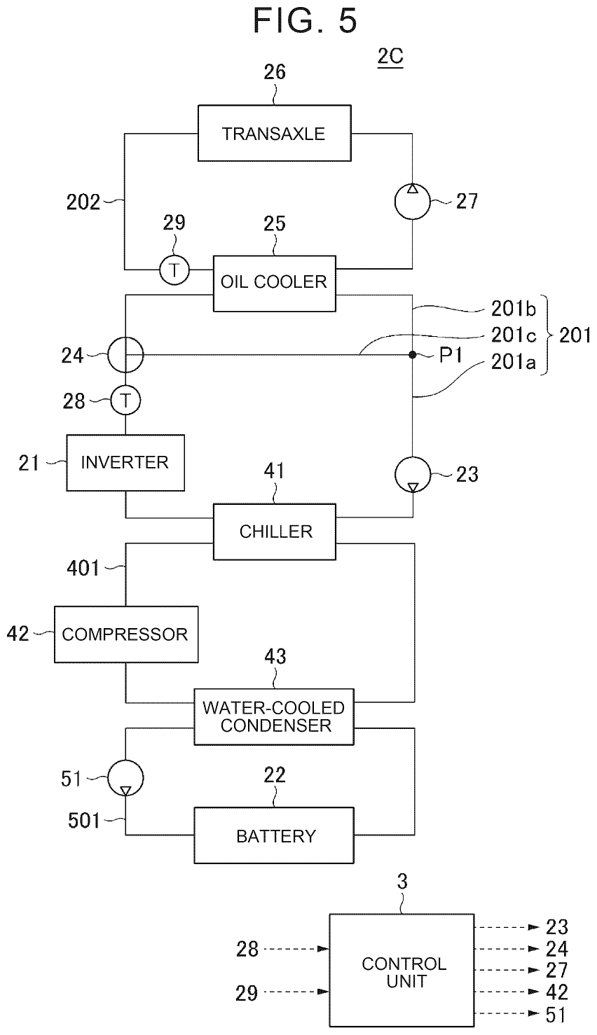

In the heat utilization circuit 2C shown in FIG. 5, a chiller 41 is disposed in place of the battery 22 of the heat utilization circuit 2 described with reference to FIG. 1, and a cooling medium circuit 401 and a coolant circuit 501 are provided. The cooling medium circuit 401 functions as a heat pump. A chiller 41, a compressor 42, and a water-cooled condenser 43 are disposed in the cooling medium circuit 401.

The cooling medium circulating in the cooling medium circuit 401 receives heat from the chiller 41, the compressor 42 is pressurized, the temperature is further increased, and flows into the water-cooled condenser 43. The water-cooled condenser 43 exchanges heat with a coolant flowing through the coolant circuit 501.

In the coolant circuit 501, a water-cooled condenser 43, a pump 51, and a battery 22 are arranged. The coolant circulating in the coolant circuit 501 is heat-exchanged by the water-cooled condenser 43 to raise the temperature of the battery 22.

The control unit 3 outputs a control signal to the pump 23, the switching valve 24, the pump 27, the compressor 42, and the pump 51.

The heat utilization circuit 2C recovers heat from the inverter 21 and the transaxle 26, and heats the battery 22 through the cooling medium circuit 401 which is a heat pump.

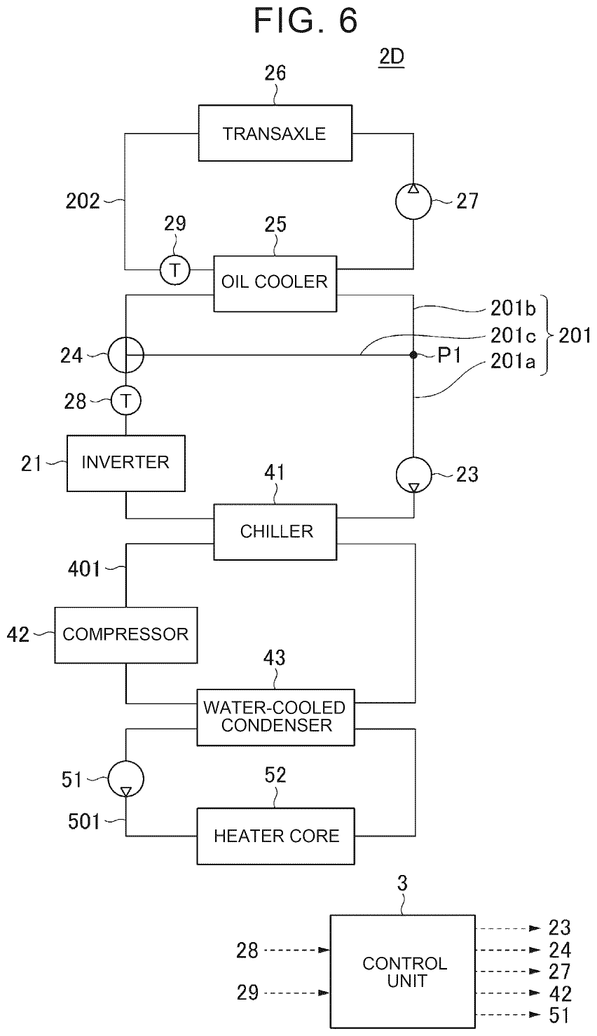

The heat utilization circuit 2D shown in FIG. 6 replaces the battery 22 of the heat utilization circuit 2C described with reference to FIG. 5 with the heater core 52. As in the heat utilization circuit 2D, heat may be applied to other warming objects, such as the heater core 52, rather than the battery 22.

The present embodiment has been described above with reference to specific examples. However, the present disclosure is not limited to these specific examples. Those skilled in the art with appropriate design modifications to these specific examples are also included in the scope of the present disclosure as long as they include the features of the present disclosure. Each element included in each of the above specific examples and the arrangement, condition, shape, etc. of each element are not limited to those illustrated herein, and can be appropriately changed. Each element included in each of the above specific examples can be appropriately combined and changed as long as there is no technical inconsistency.

### Additional Remarks

The following Appendices 1 to 4 can be arbitrarily combined as long as they are not technically inconsistent.

### Appendix 1

A heat utilization circuit 2, 2A, 2B, 2C, 2D includes:
a first cooling channel 201, 201A, 201B through which a cooling medium for cooling the inverter 21 flows; and
a second cooling channel 202, 202A, 202B through which a cooling medium for cooling the transaxle 26 flows.

The heat utilization circuit 2, 2A, 2B, 2C, 2D is configured to
when the temperature of the cooling medium cooled by the transaxle 26 is equal to or higher than the temperature of the cooling medium cooled by the inverter 21, perform heat exchange between the cooling medium cooled by the inverter 21 and the transaxle 26, and
when the temperature of the cooling medium that has cooled the transaxle 26 is lower than the temperature of the cooling medium that has cooled the inverter 21, reduce the heat exchange between the cooling medium that has cooled the inverter 21 and the transaxle 26.

The transaxle 26 has a larger heat capacity in the heat transfer path from the heat generating portion to the cooling medium than the inverter 21 and the like. Therefore, even if the temperature of the transaxle 26 itself rises, it may take a relatively long time for the cooling medium to rise in temperature. According to Appendix 1, when the temperature of the cooling medium cooled by the transaxle 26 is lower than the temperature of the cooling medium cooled by the inverter 21, heat exchange between the cooling medium cooled by the inverter 21 and the transaxle 26 is suppressed. Therefore, the temperature of the cooling medium heated by cooling the inverter 21 is suppressed from being lowered by heat exchange with the transaxle 26. By exchanging heat with the inverter 21, the heat of the cooling medium whose temperature is increased can be effectively utilized.

### Appendix 2

In the heat utilization circuit 2, 2A, 2C, 2D according to Appendix 1,
a first cooling medium for cooling the inverter flows through the first cooling channel 201, 201A,
a second cooling medium for cooling the transaxle flows through a second cooling channel 202, 202A. The heat utilization circuit further includes an oil cooler 25 as a heat exchanger for performing heat exchange between the first cooling medium and the second cooling medium.

When the temperature of the second cooling medium cooled in the transaxle 26 is equal to or higher than the temperature of the first cooling medium cooled in the inverter 21, heat exchange in the heat exchanger is performed.

When the temperature of the second cooling medium that has cooled the transaxle 26 is lower than the temperature of the first cooling medium that has cooled the inverter 21, the heat exchange in the heat exchanger is suppressed.

According to Appendix 2, an oil cooler 25 as a heat exchanger for performing heat exchange between the first cooling medium and the second cooling medium is provided. Therefore, the first cooling medium and the second cooling medium can be made different from each other, and a cooling medium suitable for the cooling target can be used.

### Appendix 3

In the heat utilization circuit 2, 2A, 2C, 2D according to Appendix 2,

The first cooling channel 201, 201A and/or the second cooling channel 202, 202A includes a heat exchange channel 201b, 202Ab that passes through an oil cooler 25 as a heat exchanger, a bypass channel 201c, 202Ac that does not pass through an oil cooler 25 as a heat exchanger, and a switching valve 24 for switching whether the 1 cooling medium and/or the 2 cooling medium flows to the heat exchange channel 201b, 202Ab, or flows to the bypass channel 201c,202Ac.

The switching valve 24,

When the temperature of the second cooling medium that has cooled the transaxle 26 is equal to or higher than the temperature of the first cooling medium that has cooled the inverter 21, the first cooling medium and/or the second cooling medium are caused to flow through the heat exchange channels 201b, 202Ab.

When the temperature of the second cooling medium that has cooled the transaxle 26 is lower than the temperature of the first cooling medium that has cooled the inverter 21, the flow rate of the first cooling medium and/or the second cooling medium to the bypass channel 201c, 202Ac is increased.

According to Appendix 3, the temperature of the second cooling medium cooling the transaxle 26 is lower than the temperature of the first cooling medium cooling the inverter 21. Here, the flow rate of the first cooling medium and/or the second cooling medium through the bypass channel 201c, 202Ac is increased. Therefore, the temperature of the cooling medium heated by cooling the inverter 21 is reliably suppressed from being lowered by heat exchange with the transaxle 26. By exchanging heat with the inverter 21, the heat of the cooling medium whose temperature is increased can be effectively utilized.

### Additional Remark 4

In the heat utilization circuit 2B according to Appendix 1,
the same cooling medium flows through the first cooling channel 201B and the second cooling channel 202B.

The heat utilization circuit further includes a bypass channel 203B in which the cooling medium cooled by the inverter 21 does not pass through the transaxle 26, and a switching valve 24 for switching whether the cooling medium flows to the second cooling channel 202B or to the bypass channel 203B,

The switching valve 24 is configured to
when the temperature of the cooling medium that has cooled the transaxle 26 is equal to or higher than the temperature of the cooling medium that has cooled the inverter 21, cause the cooling medium that has cooled the inverter 21 to flow to the second cooling channel 202B, and when the temperature of the cooling medium that has cooled the transaxle 26 is lower than the temperature of the cooling medium that has cooled the inverter 21, increases an amount of the cooling medium that has cooled the inverter 21 to be caused to flow to the bypass channel 203B.

According to Appendix 4, even in a mode in which the same cooling medium flows through the first cooling channel 201B and the second cooling channel 202B, there is a simple configuration in which the bypass channel 203B and the switching valve 24 are provided. As a result, the temperature of the cooling medium heated by cooling the inverter 21 is suppressed from being lowered by heat exchange with the transaxle 26. By exchanging heat with the inverter 21, the heat of the cooling medium whose temperature is increased can be effectively utilized.

What is claimed is:

1. A heat utilization circuit comprising:
a first cooling channel through which a cooling medium configured to cool an inverter flows; and
a second cooling channel through which a cooling medium configured to cool a transaxle flows, wherein the heat utilization circuit is configured to
when a temperature of the cooling medium that has cooled the transaxle is equal to or higher than a temperature of the cooling medium that has cooled the inverter, perform heat exchange between the cooling medium that has cooled the inverter and the transaxle, and
when the temperature of the cooling medium that has cooled the transaxle is lower than the temperature of the cooling medium that has cooled the inverter, reduce the heat exchange between the cooling medium that has cooled the inverter and the transaxle.

2. The heat utilization circuit according to claim 1, wherein:
a first cooling medium configured to cool the inverter flows through the first cooling channel;
a second cooling medium configured to cool the transaxle flows through the second cooling channel;
the heat utilization circuit further includes a heat exchanger configured to perform heat exchange between the first cooling medium and the second cooling medium; and
the heat utilization circuit is configured to
when a temperature of the second cooling medium that has cooled the transaxle is equal to or higher than a temperature of the first cooling medium that has cooled the inverter, perform the heat exchange in the heat exchanger, and
when the temperature of the second cooling medium that has cooled the transaxle is lower than the temperature of the first cooling medium that has cooled the inverter, reduce the heat exchange in the heat exchanger.

3. The heat utilization circuit according to claim 2, wherein:
either or both of the first cooling channel and the second cooling channel include a heat exchange channel that passes through the heat exchanger, a bypass channel that does not pass through the heat exchanger, and a switching valve configured to selectively cause either or both of the first cooling medium and the second cooling medium to flow to either the heat exchange channel or the bypass channel; and
the switching valve is configured to
when the temperature of the second cooling medium that has cooled the transaxle is equal to or higher than the temperature of the first cooling medium that has cooled the inverter, cause either or both of the first cooling medium and the second cooling medium to flow to the heat exchange channel, and
when the temperature of the second cooling medium that has cooled the transaxle is lower than the temperature of the first cooling medium that has cooled the inverter, cause either or both of the first cooling medium and the second cooling medium to flow to the bypass channel.

4. The heat utilization circuit according to claim 1, wherein:
the same cooling medium flows through the first cooling channel and the second cooling channel;
the heat utilization circuit further includes
a bypass channel configured not to cause the cooling medium that has cooled the inverter to flow through the transaxle, and
a switching valve configured to selectively cause the cooling medium to flow to either the second cooling channel or the bypass channel; and
the switching valve is configured to
when the temperature of the cooling medium that has cooled the transaxle is equal to or higher than the temperature of the cooling medium that has cooled the inverter, cause the cooling medium that has cooled the inverter to flow to the second cooling channel, and
when the temperature of the cooling medium that has cooled the transaxle is lower than the temperature of the cooling medium that has cooled the inverter, increase an amount of the cooling medium that is caused to flow to the bypass channel.
